(19) United States
(12) Patent Application Publication
(10) Pub. No.: US 2025/0344383 A1
(43) Pub. Date: Nov. 6, 2025

(54) MEMORY CELL INCLUDING ELECTRO-CHEMICAL MEMORY ELEMENT AND SEMICONDUCTOR DEVICE INCLUDING THE SAME

(71) Applicant: SK hynix Inc., Icheon-si (KR)

(72) Inventors: Mir IM, San Jose, CA (US); Won Tae KOO, Icheon-si (KR); Pil Hoon JUNG, Icheon-si (KR)

(21) Appl. No.: 18/931,864

(22) Filed: Oct. 30, 2024

(30) Foreign Application Priority Data
May 3, 2024 (KR) 10-2024-0059466

(51) Int. Cl. H10B 41/30; G11C 16/04; G11C 16/08; H01L 29/423; H10B 41/41

(52) U.S. Cl. CPC H10B 41/30; G11C 16/0433; G11C 16/08; H10B 41/41; H10D 30/6891

(57) ABSTRACT

A semiconductor device includes an electro-chemical memory element and a control element electrically connected to each other. The electro-chemical memory element includes a source line disposed on a plane, a bit line disposed to be spaced apart from the source line and extending in a vertical direction, a storage channel layer disposed to be connected to the source line and the bit line on the plane, an electrolyte layer disposed on the storage channel layer, an ion reservoir layer disposed on the electrolyte layer, and a floating gate electrode layer disposed on the ion reservoir layer. The control element includes a control channel structure disposed on the floating gate electrode layer, a control source line disposed on the control channel structure, a control gate dielectric layer disposed on a side surface of the control channel structure, and a control word line disposed on the control gate dielectric layer.

### CROSS-REFERENCE TO RELATED APPLICATION

The present application claims priority under 35 U.S.C. § 119(a) to Korean Application No. 10-2024-0059466, filed on May 3, 2024, which is incorporated herein by reference in its entirety.

### BACKGROUND

### 1. Technical Field

The present disclosure generally relates to a memory cell and a semiconductor device including the same and, more particularly, to a memory cell including an electro-chemical memory element and a semiconductor device including the same.

### 2. Related Art

An electro-chemical memory device is emerging as an example of a non-volatile memory device. The electro-chemical memory device includes an ion receiving layer and an ion supply layer, and an electrolyte layer disposed between the ion receiving layer and the ion supply layer.

The electro-chemical memory device allows ions to be exchanged between the ion receiving layer and the ion supply layer under an external stimulus. The electro-chemical memory device uses the electrical resistance properties of the ion receiving layer, which changes depending on the concentration of the ions contained in the ion receiving layer, to store signal information. Because the electrical resistance of the ion receiving layer is inversely proportional to the concentration of the ions contained in the ion receiving layer, the electro-chemical memory device can implement a multi-level signal by employing the different resistance states of the ion receiving layer as signal information. Recently, research has been conducted to increase the density of memory cells by reducing the size of the electro-chemical memory device.

### SUMMARY

A memory cell according to an embodiment of the present disclosure may include an electro-chemical memory element and a control element that are electrically connected to each other. The electro-chemical memory element may include a source line disposed on a plane, a bit line disposed to be spaced apart from the source line and extending in a direction perpendicular to the plane, a storage channel layer disposed on the plane to be connected to the source line and the bit line, an electrolyte layer disposed on the storage channel layer, an ion reservoir layer disposed on the electrolyte layer, and a floating gate electrode layer disposed on the ion reservoir layer. The control element may include a control channel structure disposed on the floating gate electrode layer, a control source line disposed on the control channel structure, a control gate dielectric layer disposed on a side surface of the control channel structure, and a control word line disposed on the control gate dielectric layer.

A semiconductor device according to an embodiment of the present disclosure may include a substrate, a bit line extending in a first direction perpendicular to a surface of the substrate, and a plurality of memory cells sharing the bit line with each other, and disposed to be spaced apart from each other in the first direction and over the substrate. Each of the plurality of memory cells may include an electro-chemical memory element. The electro-chemical memory element may include a source line disposed to extend in a second direction on a plane perpendicular to the first direction over the substrate, a storage channel layer disposed to electrically connect the source line to the bit line on the plane, an electrolyte layer disposed on the storage channel layer, an ion reservoir layer disposed on the electrolyte layer, and a floating gate electrode layer disposed on the ion reservoir layer.

A semiconductor device according to another embodiment of the present disclosure may include a substrate, first and second bit lines extending in a first direction perpendicular to a surface of the substrate, and a pair of memory cells electrically connected to corresponding bit lines of the first and second bit lines and disposed to be spaced apart from each other. Each of the pair of memory cells may include an electro-chemical memory element. The electro-chemical memory element may include a source line disposed to extend in a second direction on a plane that is perpendicular to the first direction over the substrate, a storage channel layer disposed to electrically connect the source line to the bit line on the plane, an electrolyte layer disposed on the storage channel layer, an ion reservoir layer disposed on the electrolyte layer, and a floating gate electrode layer disposed on the ion reservoir layer. The source lines of the pair of memory cells may be electrically connected to each other.

### BRIEF DESCRIPTION OF THE DRAWINGS

FIG. 1 is a circuit diagram of a memory cell according to an embodiment of the present disclosure.

FIG. 2 is a schematic cross-sectional view illustrating a memory cell according to an embodiment of the present disclosure.

FIGS. 3 and 4 are schematical cross-sectional views illustrating an operation method of a memory cell according to an embodiment of the present disclosure.

FIGS. 5 and 6 are graphs schematically illustrating the conductance of a storage channel layer depending on a write voltage applied to a memory cell according to an embodiment of the present disclosure.

FIGS. 7 and 8 are circuit diagrams of a semiconductor device according to an embodiment of the present disclosure.

FIG. 9 is a schematic cross-sectional view illustrating a semiconductor device according to another embodiment of the present disclosure.

FIG. 10 is a view illustrating a semiconductor device of FIG. 9 taken along a line I-I′ and shown on an x-y plane.

FIG. 11 is a view illustrating a semiconductor device of FIG. 9 taken along a line II-II′ and shown on an x-y plane.

FIG. 12 is a view illustrating a semiconductor device of FIG. 9 taken along a line III-III′ and shown on an x-y plane.

FIG. 13 is a view illustrating a semiconductor device of FIG. 9 taken along a line IV-IV′ and shown on an x-y plane.

FIG. 14 is a circuit diagram of a semiconductor device according to another embodiment of the present disclosure.

FIG. 15 is a schematic cross-sectional view illustrating a semiconductor device according to another embodiment of the present disclosure.

FIG. 16 is a schematic cross-sectional view illustrating a semiconductor device according to another embodiment of the present disclosure.

FIG. 17 is a schematic cross-sectional view illustrating a semiconductor device according to another embodiment of the present disclosure.

FIGS. 18 to 20 are schematic cross-sectional views illustrating arrangements of memory cells of a semiconductor device according to various embodiments of the present disclosure.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. The terms used herein may correspond to words selected in consideration of their functions in the embodiments, and the meanings of the terms may be construed to be different according to the ordinary skill in the art to which the embodiments belong. If expressly defined in detail, the terms may be construed according to the definitions. Unless otherwise defined, the terms (including technical and scientific terms) used herein have the same meaning as commonly understood by one of ordinary skill in the art to which the embodiments belong.

In addition, expression of a singular form of a word should be understood to include the plural forms of the word unless clearly used otherwise in the context. It will be understood that the terms “comprise”, “include”, or “have” are intended to specify the presence of a feature, a number, a step, an operation, a component, an element, a part, or combinations thereof, but not used to preclude the presence or possibility of addition one or more other features, numbers, steps, operations, components, elements, parts, or combinations thereof.

Terms used in the specification of the present application are terms selected in consideration of functions in the presented embodiments, and the meaning of the terms may vary depending on the intention or customs of a user or operator in the technical field. The meanings of the terms used follow the definitions defined when specifically defined herein, and may be interpreted as meanings generally recognized by those skilled in the art in the absence of specific definitions.

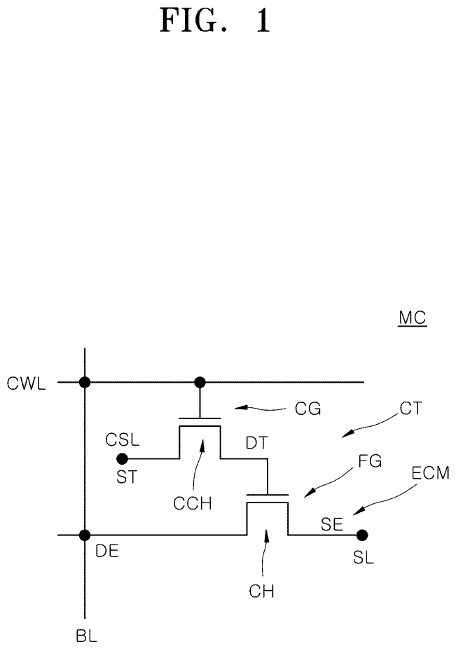

FIG. 1 is a circuit diagram of a memory cell according to an embodiment of the present disclosure. Referring to FIG. 1, a memory cell MC includes a control element CT and an electro-chemical memory element ECM, which are electrically connected to each other. The control element CT may be a field effect transistor device that is turned on depending on a gate signal applied to a control gate electrode CG, which transmits a voltage of a control source line CSL to a floating gate electrode FG of the electro-chemical memory element ECM. The electro-chemical memory element ECM may be a non-volatile memory device that stores signal information in a channel CH of the transistor device according to a write voltage applied to the floating gate electrode FG.

Referring to FIG. 1, the control element CT includes the control gate electrode CG electrically connected to a control word line CWL, a control source electrode ST electrically connected to the control source line CSL, a control drain electrode DT electrically connected to the floating gate electrode FG of the electro-chemical memory element ECM, and a control channel CCH between the control source electrode ST and the control drain electrode DT.

The electro-chemical memory element ECM includes the floating gate electrode FG electrically connected to the control drain electrode DT of the control element CT, a source electrode SE electrically connected to a source line SL, a drain electrode DE electrically connected to a bit line BL, a storage channel CH between the source electrode SE and the drain electrode DE. The storage channel CH may function as a memory layer that stores signal information of the memory cell MC.

In an embodiment, a write operation of the memory cell MC may proceed as follows. Depending on a voltage signal applied to the control word line CWL, the control element CT, which is a field effect transistor, is turned on or off. When the control element CT is turned on, a voltage of the control source line CSL is applied to the floating gate electrode FG of the electro-chemical memory element ECM through the control source electrode ST, the control channel CCH, and the control drain electrode DT. During the write operation, a ground voltage is applied to the source electrode SE and the drain electrode DE of the electro-chemical memory element ECM.

In an embodiment, the control element CT is an N-type field effect transistor, and when a gate voltage of a positive polarity is applied to the control gate electrode CG of the control element CT from the control word line CWL, the control element CT is turned on. With the control element CT turned on, when a control voltage of positive polarity is applied to the control source line CSL, a first write voltage of positive polarity is applied to the floating gate electrode FG. With the control element CT is turned on, when a control voltage of negative polarity is applied to the control source line CSL, a second write voltage of negative polarity is applied to the floating gate electrode FG.

In another embodiment, the control element CT is a P-type field effect transistor, and when a gate voltage of negative polarity is applied to the control gate electrode CG of the control element CT from the control word line CWL, the control element CT is turned on. With the control element CT turned on, when a control voltage of positive polarity is applied to the control source line CSL, a first write voltage of positive polarity is applied to the floating gate electrode FG. With the control element CT turned on, when a control voltage of negative polarity is applied to the control source line CSL, a second write voltage of negative polarity is applied to the floating gate electrode FG.

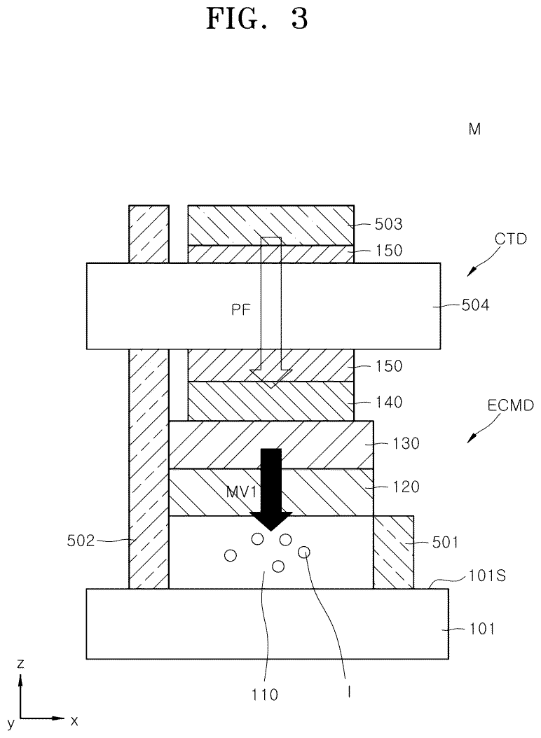

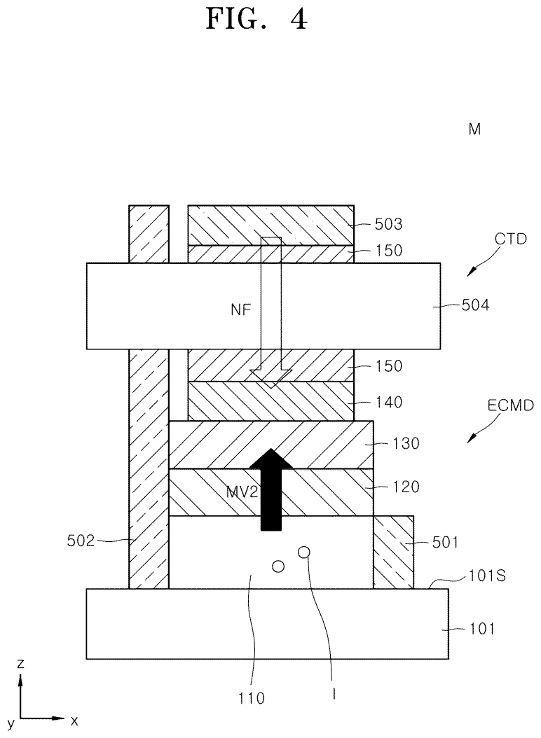

When the first write voltage is applied to the floating gate electrode FG, according to an operation method described later with reference to FIG. 3, a conductance value of the storage channel CH of the electro-chemical memory element ECM may increase. The increased conductance value of the storage channel CH may be maintained even after the control element CT is turned off. The increased conductance value may be stored as first signal information in the electro-chemical memory element ECM of the memory cell MC. When the second write voltage is applied to the floating gate electrode FG, according to an operation method described with reference to FIG. 4, the conductance value of the storage channel CH of the electro-chemical memory element ECM may decrease. The decreased conductance value of the storage channel CH may be maintained even after the control element CT is turned off. The decreased conductance value of the storage channel CH may be stored as second signal information in the electro-chemical memory element ECM of the memory cell MC.

According to an embodiment of the present disclosure, each of the first and second write voltages may be applied in the form of a pulse voltage by the control word line CWL and the control source line CSL of the control element CT. As will be described later, the conductance value of the storage channel CH of the electro-chemical memory element ECM may vary linearly depending on the number of the pulse voltages. Accordingly, the electro-chemical memory element ECM can use a plurality of different channel conductances that change linearly to store multi-level signal information.

In an embodiment, an arithmetic operation on the memory cell MC may proceed as follows. With the control element CT turned off, a predetermined source voltage is applied to the source line SL. The source voltage input to the source electrode SE is output to the bit line BL in the form of a bit line current after a multiplication operation is performed with the conductance value of the storage channel CH. Accordingly, the arithmetic operation can be performed on the signal information stored in the electro-chemical memory element ECM of the memory cell MC.

Various embodiments of the present disclosure described below include a memory cell having a circuit configuration of FIG. 1 and a semiconductor device including the memory cell. The memory cell may have a structure in which the electro-chemical memory element and the control element are three-dimensionally stacked over a substrate. The semiconductor device may have a three-dimensional structure in which memory cells are sequentially stacked over the substrate.

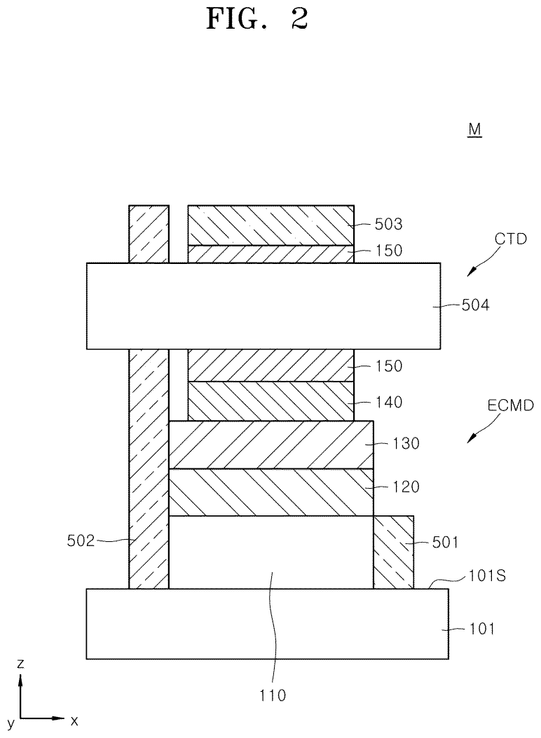

FIG. 2 is a schematic cross-sectional view illustrating a memory cell according to an embodiment of the present disclosure. Referring to FIG. 2, a memory cell M includes an electro-chemical memory element ECMD and a control element CTD that are electrically connected to each other. The electro-chemical memory element ECMD includes a source line 501, a storage channel layer 110, and a bit line 502 that are disposed on a plane 101S of a substrate 101. The source line 501 and the bit line 502 may be conductive pattern structures. In addition, the electro-chemical memory element ECMD includes an electrolyte layer 120 disposed on the storage channel layer 110, an ion reservoir layer 130 disposed on the electrolyte layer 120, and a floating gate electrode layer 140 disposed on the ion reservoir layer 130. The control element CTD includes a control channel structure 150 disposed on the floating gate electrode layer 140 of the electro-chemical memory element ECMD, and a control source line 503 disposed on the control channel structure 150. In addition, the control element CTD includes a control gate dielectric layer (not shown) disposed on a side surface of the control channel structure 150 and a control word line 504 disposed to cover the control gate dielectric layer.

Referring to FIG. 2, the substrate 101 may include a semiconductor material. Specifically, the semiconductor material may include silicon (Si), germanium (Ge), gallium arsenide (GaAs), molybdenum selenide (MoSe₂), hafnium selenide (HfSe₂), indium selenide (InSe), gallium selenide (GaSe), black phosphorus, and indium-gallium-zinc oxide (IGZO), or a combination of two or more thereof. The substrate 101 may be doped with an n-type or p-type dopant to have a predetermined conductivity. Although not shown, the substrate 101 includes well regions doped with an n-type or p-type dopant.

The storage channel layer 110 is disposed on the plane 101S of the substrate 101. The storage channel layer 110 includes ions that are exchangeable with the ion reservoir layer 130. The ions may include, for example, hydrogen (H) ions, lithium (Li) ions, sodium (Na) ions, potassium (K) ions, oxygen (O) ions, or a combination of two or more thereof. Additionally, the storage channel layer 110 may include a material that receives the ions. Examples of materials that may receive the ions may include metal, metal oxide, metal chalcogenide, polycrystalline silicon, or a combination of two or more thereof.

Referring to FIG. 2, the source line 501 and the bit line 502 are disposed on the plane 101S of the substrate 101. Each of the source line 501 and the bit line 502 is electrically connected to a corresponding end of both ends of the storage channel layer 110, located on opposite sides. Each of the source line 501 and the bit line 502 may include a conductive material. The conductive material may include, for example, a doped semiconductor material, metal, conductive metal nitride, conductive metal carbide, conductive metal silicide, or conductive metal oxide. The conductive material may include, for example, n-type doped silicon (Si), platinum (Pt), gold (Au), palladium (Pd), molybdenum (Mo), nickel (Ni), tungsten (W), titanium (Ti), copper (Cu), aluminum (Al), ruthenium (Ru), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

The source line 501 and the bit line 502 may be line-shaped conductive patterns extending in different directions. The bit line 502 may include a pattern structure extending in a first direction (that is, z-direction) perpendicular to the plane 101S. The source line 501 may include a pattern structure extending in a second direction (that is, y-direction) perpendicular to the first direction on the plane 101S. In FIG. 2, the source line 501 and the bit line 502 are disposed to be in contact with the storage channel layer 110, but the present disclosure is not necessarily limited thereto. Other conductive layers may be added between the source line 501 and the storage channel layer 110 and/or between the bit line 502 and the storage channel layer 110.

Referring to FIG. 2, the electrolyte layer 120 is disposed on the storage channel layer 110. The electrolyte layer 120 provides a path for ions to move between the storage channel layer 110 and the ion reservoir layer 130. Specifically, when an electric field is formed between the storage channel layer 110 and the floating gate electrode layer 140, the ions of the ion reservoir layer 130 may pass through the electrolyte layer 120 and move to the storage channel layer 110, or the ions of the storage channel layer 110 may pass through the electrolyte layer 120 and move to the ion reservoir layer 130. The electrolyte layer 120 may be formed of various materials depending on ion type. As described below, the electrolyte layer 120 may include various materials according to materials of the ion reservoir layer 130.

In FIG. 2, the electrolyte layer 120 and the storage channel layer 110 are disposed to completely overlap each other in the z-direction, but the present disclosure is not necessarily limited thereto. In some other embodiments, the electrolyte layer 120 and the storage channel layer 110 may be disposed to partially overlap each other in the z-direction. In some other embodiments, the electrolyte layer 120 may be disposed to cover the storage channel layer 110 and additionally at least a portion of an upper surface of the source line 501. In some other embodiments, unlike the illustration of FIG. 2, the electrolyte layer 120 may be disposed to be spaced apart from the source line 510 and the bit line 502 in a lateral direction (for example, x-direction). Accordingly, the electrolyte layer 120 can maintain a non-contact state not only with the source line 501 but also with the bit line 502.

Referring to FIG. 2, the ion reservoir layer 130 is disposed on the electrolyte layer 120. The ion reservoir layer 130 may include ions that move among layers. When an electric field is formed between the storage channel layer 110 and the floating gate electrode layer 140, the ion reservoir layer 130 may provide ions to the storage channel layer 110 or may receive the ions from the storage channel layer 110.

In an embodiment, the ion reservoir layer 130 may include, for example, palladium hydride, magnesium hydride, yttrium hydride, silicon containing hydrogen, gallium arsenide containing hydrogen, or a combination of two or more thereof. The electrolyte layer 120 may include proton exchange polymer, metal-organic framework, sulfonate graphene, polymer-graphene composites, or a combination of two or more thereof. Additionally, the storage channel layer 110 may include palladium (Pd), magnesium (Mg), yttrium (Y), or a combination of two or more thereof.

In another embodiment, the ion reservoir layer 130 may include, for example, LiₓMO₂ (0<x≤1), where M includes at least one of titanium (Ti), vanadium (V), chromium (Cr), manganese (Mn), iron (Fe), cobalt (Co), and nickel (Ni)), NaₓMO₂ (0<x≤1, M includes at least one of iron (Fe), cobalt (Co), manganese (Mn), nickel (Ni), and copper (Cu)), KₓMnO₂ (0<x≤1), KₓCoO₂ (0<x≤1), or a combination of two or more thereof. The electrolyte layer 120 may include, for example, lithium phosphorus oxynitride (LiPON), sulfonated tetrafluoroethylene based fluoropolymer-copolymer, polystyrene-based membrane, sulfonated polyimide (SPI)-based membrane, polyphosphazene-based membrane, polybenzimidazole (PBI)-based membrane, or a combination of two or more thereof. In addition, the storage channel) layer 110 may include, for example, tungsten oxide (WO₃), molybdenum sulfide (MoS₂), tungsten sulfide (WS₂), tin sulfide (SnS₂), or a combination of two or more thereof.

In another embodiment, the ion reservoir layer 130 may include gadolinium oxide (GdOₓ (0<x≤1)), molybdenum oxide (MoOₓ (0<x≤1)), tungsten oxide (WO₃₋ₓ (0<x≤1)), copper oxide (CuO), titanium oxide (TiO₂), or a combination of two or more thereof. The electrolyte layer 120 may include, for example, hafnium oxide (HfO₂), zirconium oxide (ZrO₂), yttria-stabilized zirconia (YSZ), oxide of barium-selenium-yttrium (Ba—Ce—Y—O), oxide of zirconium-scandium (Zr—Sc—O), or a combination of two or more thereof. In addition, the storage channel layer 110 may include, for example, tungsten oxide (WO₃), molybdenum oxide (MoO₃), selenium oxide (CeO₃), iron oxide (Fe₃O₄), zirconium oxide (ZrO₂), cobalt oxide (CoO), vanadium oxide (V₂O₅), titanium oxide (TiO₂), strontium titanium oxide (SrTiO₃), yttrium oxide (Y₂O₃), or a combination of two or more thereof.

In FIG. 2, the ion reservoir layer 130 and the electrolyte layer 120 are disposed to completely overlap each other in the z-direction, but the present disclosure might not necessarily be limited thereto. In some embodiments, the ion reservoir layer 130 and the electrolyte layer 120 may be disposed to partially overlap each other in the z-direction. Additionally, in FIG. 2, the ion reservoir layer 130 is shown to be in contact with the bit line 502, but the present disclosure is not necessarily be limited thereto. In some embodiments, the ion reservoir layer 130 may be disposed on the electrolyte layer 120 to be spaced apart from the bit line 502 in the lateral direction (for example, x-direction). Accordingly, the ion reservoir layer 130 can maintain a non-contact state with the bit line 502.

Referring to FIG. 2, the floating gate electrode layer 140 is disposed on the ion reservoir layer 130. The floating gate electrode layer 140 may include a conductive material. The conductive material may include, for example, a doped semiconductor material, metal, conductive metal nitride, conductive metal carbide, conductive metal silicide, or conductive metal oxide. The conductive material may include, for example, n-type doped silicon (Si), platinum (Pt), gold (Au), palladium (Pd), molybdenum (Mo), nickel (Ni), tungsten (W), titanium (Ti), copper (Cu), aluminum (Al), ruthenium (Ru), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

The floating gate electrode layer 140 is disposed to be spaced apart from the bit line 502 in a lateral direction (for example, x-direction) and to be electrically insulated from the bit line 502. In FIG. 2, the floating gate electrode layer 140 is shown to completely overlap the ion reservoir layer 130 in the z-direction, but the present disclosure is not necessarily limited thereto. The floating gate electrode layer 140 may be disposed to partially overlap the ion reservoir layer 130 in the z-direction.

Referring to FIG. 2, the control channel structure 150 of the control element CTD is disposed on the floating gate electrode layer 140 of the electro-chemical memory element ECMD. The control channel structure 150 of the control element CTD may be stacked on the floating gate electrode layer 140 in z-direction. The control channel structure 150 may include a pillar structure connecting the floating gate electrode layer 140 to the control source line 503. The pillar structure may have a shape or structure that is a polygonal pillar, a cylinder, or an elliptical pillar.

The control channel structure 150 is disposed to overlap the floating gate electrode layer 140 in the first direction (that is, z-direction). The control channel structure 150 is disposed to be spaced apart from the bit line 502 in the lateral direction (for example, x-direction). Accordingly, the control channel structure 150 is electrically insulated from the bit line 502.

The control channel structure 150 may include, for example, a semiconductor material, conductive metal oxide, transition metal chalcogenide, or a combination of two or more thereof. The control channel structure 150 may have n-type semiconductor characteristics or p-type semiconductor characteristics.

As an example, the semiconductor material may include silicon (Si), germanium (Ge), gallium arsenide (GaAs), or a combination of two or more thereof. The semiconductor material may include an n-type or p-type dopant. As another example, the conductive metal oxide may include indium oxide (In₂O₃), indium gallium zinc oxide (InGaZnO₄), zinc oxide (ZnO), indium gallium oxide (InGaO₃), or a combination of two or more thereof. The conductive metal oxide may include a dopant. The dopant may include titanium (Ti), tungsten (W), silicon (Si), or a combination of two or more thereof.

The control source line 503 is disposed on the control channel structure 150. In an embodiment, the control source line 503 is disposed over the control channel structure 150 in z-direction. The control source line 503 may be a line-shaped conductive pattern extending in one direction. In an embodiment, the control source line 503 may include a pattern structure extending in the second direction (that is, y-direction) on a plane (that is, x-y plane) perpendicular to the first direction (that is, z-direction). The control source line 503 may include substantially the same conductive material as described with respect to the source line 501 or bit line 502.

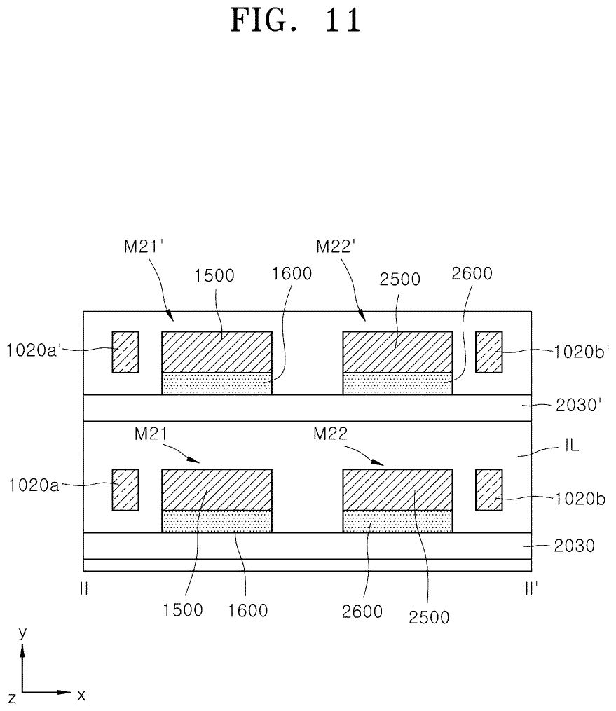

The control gate dielectric layer (not shown) is disposed on a side surface of the control channel structure 150. As an example, the control gate dielectric layer may be disposed on an x-z plane. The control gate dielectric layer is disposed to have a predetermined thickness on a side surface in the second direction (that is, y-direction). The control word line 504 is disposed on the control gate dielectric layer in the second direction (that is, y-direction). The control gate dielectric layer may be disposed to be covered by the control word line 504. The arrangement of the control gate dielectric layer and the control word line 504 will be described in more detail through the arrangement of control gate dielectric layers 1600, 1600′, 2600, and 2600′ and control word lines 2030 and 2030′ of FIG. 11, which will be described below.

The control gate dielectric layer is disposed between the control word line 504 and the control channel structure 150 and may function as a gate dielectric layer of the control element CTD, which is a field effect transistor. The control gate dielectric layer may include, for example, oxide, nitride, oxynitride, or a combination of two or more thereof.

Referring to FIG. 2, the control word line 504 extends in a third direction that is not parallel to the first direction (that is, z-direction) while disposed on a plane (for example, x-z plane) parallel to the first direction. In an embodiment, the third direction may be the x-direction, which is perpendicular to the first and second directions. Accordingly, the bit line 502, the control source line 503, and the control word line 504 may extend respectively in directions perpendicular to each other.

The control word line 504 is disposed to be spaced apart from the bit line 502 in the second direction (that is, y-direction). Accordingly, the control word line 504 can be electrically insulated from the bit line 502. The control word line 504 may include substantially the same conductive material as described with reference to the source line 501 or the bit line 502.

In FIG. 2, an interlayer insulation layer may be disposed in spaces between numbered components that are disposed over the substrate 101. An interlayer insulation layer may serve to electrically insulate two numbered components from each other.

In some embodiments, the electro-chemical memory element ECMD is disposed on a plane located over the substrate 101 not directly on the substrate 101. In this case, the source line 501, the storage channel layer 110, and the bit line 502 are disposed on the same plane over the substrate 101. A control circuit structure that controls or drives the memory cell M or an interconnection structure may be disposed between the substrate 101 and the plane on which the electro-chemical memory element ECMD is disposed.

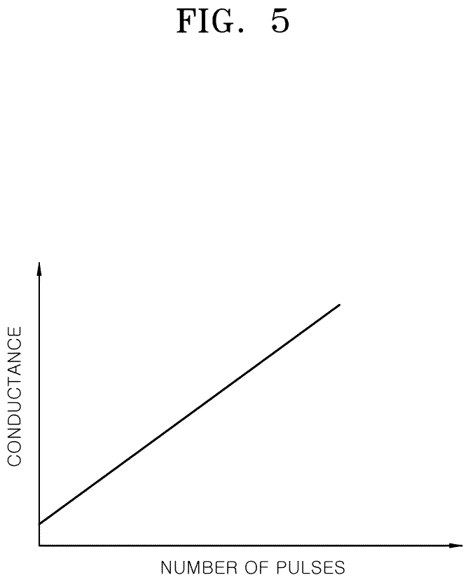

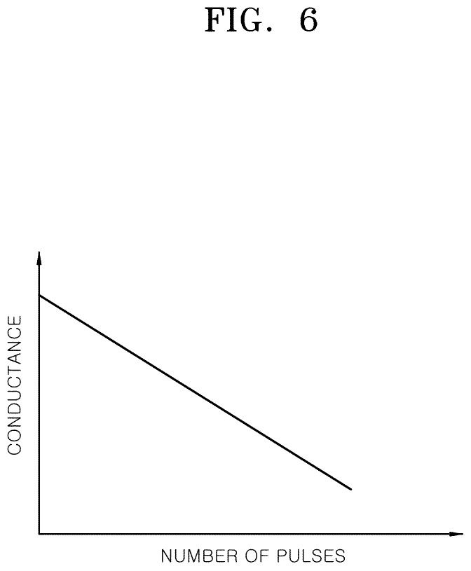

FIGS. 3 and 4 are schematic cross-sectional views illustrating an operation method of a memory cell according to an embodiment of the present disclosure. Specifically, FIG. 3 schematically illustrates a first write operation of a memory cell M of FIG. 2. FIG. 4 schematically illustrates a second write operation of a memory cell M of FIG. 2. FIGS. 5 and 6 are graphs schematically illustrating the conductance value of a storage channel layer depending on a write voltage applied to a memory cell according to an embodiment of the present disclosure.

Referring to FIG. 3, a first write operation may proceed as follows. A gate voltage of a threshold voltage or higher is applied to the control word line 504 to turn on the control element CTD and to form a conductive channel in the control channel structure 150. In an embodiment, when the control channel structure 150 has p-type semiconductor characteristics, the gate voltage may have a positive polarity. In another embodiment, when the control channel structure 150 has n-type semiconductor characteristics, the gate voltage May have a negative polarity.

With the control element CTD turned on, a first control voltage of the positive polarity is applied to the control source line 503. The first control voltage may apply a first write voltage having positive polarity to the floating gate electrode layer 140 of the electro-chemical memory element ECMD through the conductive channel. In this case, a ground voltage is applied to the source line 501 and the bit line 502 of the electro-chemical memory element ECMD. In FIG. 3, the process of applying the first write voltage is shown as ‘PF’.

The first write voltage forms an electric field between the floating gate electrode layer 140 and the storage channel layer 110. In an embodiment, the electric field moves positive ions distributed within the ion reservoir layer 130 to the storage channel layer 110 through the electrolyte layer 120. In FIG. 3, the process of moving the positive ions is shown as ‘MV1’. For example, the positive ions may include hydrogen (H) ions, lithium (Li) ions, sodium (Na) ions, potassium (K) ions, or a combination of two or more thereof. In another embodiment (not illustrated), the electric field moves oxygen ions with negative charges distributed within the storage channel layer 110 to the ion reservoir layer 130. As the oxygen ions move, oxygen vacancies with positive charges are generated in the storage channel layer 110.

As a result, the concentration of the positive ions or the concentration of the oxygen vacancies in the storage channel layer 110 is increased due to the first write voltage. As the concentration of the positive ions or the concentration of the oxygen vacancies in the storage channel layer 110 is increased, the channel conductance of the storage channel layer 110 is increased. In FIG. 3, the positive ions or oxygen vacancies distributed within the storage channel layer 110 are indicated by reference mark ‘I’.

After the channel conductance of the storage channel layer 110 is increased, the control voltage is removed to turn off the control element CTD. Accordingly, the first write voltage applied to the floating gate electrode layer 140 is removed. Even after the first write voltage is removed, the storage channel layer 110 may maintain an increased channel conductance so that the electro-chemical memory element ECMD can store the channel conductance as signal information.

In an embodiment, the channel conductance of the storage channel layer 110 may increase linearly in proportion to the concentration of positive ions or the concentration of oxygen vacancies. Accordingly, the storage channel layer 110 is capable of storing a plurality of channel conductances that are adjusted depending on the first write voltage.

In an embodiment, the first write voltage may be provided in the form of pulse voltage. Specifically, with the control element CTD turned on, the first control voltage, in the form of a pulse voltage, is applied to the control source line 503, so that the first write voltage in the form of a pulse voltage may be applied to the floating gate electrode layer 140.

Referring to FIG. 5, as the number of pulses in the first write voltage, which are applied to the floating gate electrode layer 140, increases, the amount of the positive ions moving from the ion reservoir layer 130 to the storage channel layer 110 or the amount of oxygen ions moving from the storage channel layer 110 to the ion reservoir layer 130 may also increase. As a result, the channel conductance of the storage channel layer 110 may increase linearly in proportion to the number of pulses of the first write voltage as shown in FIG. 5. Accordingly, it is possible to effectively use a plurality of channel conductance values to store multi-level signal information, where the plurality of channel conductance values of the storage channel layer 110 vary according to a linear relationship.

Referring to FIG. 4, a second write operation may proceed as follows. As described above, the gate voltage of a threshold voltage or higher is applied to the control word line 504 to turn on the control element CTD and form a conductive channel in the control channel structure 150.

With the control element CTD turned on, a second control voltage having a negative polarity is applied to the control source line 503. The second control voltage may apply a second write voltage having a negative polarity to the floating gate electrode layer 140 of the electro-chemical memory element ECMD through the conductive channel. In this case, ground voltage is applied to the source line 501 and the bit line 502 of the electro-chemical memory element ECMD. In FIG. 4, the process of applying the second write voltage is shown as ‘NF’.

The second write voltage forms an electric field between the floating gate electrode layer 140 and the storage channel layer 110. In an embodiment, the electric field moves positive ions distributed within the storage channel layer 110 to the ion reservoir layer 130 through the electrolyte layer 120. In FIG. 4, the process of moving the positive ions is shown as ‘MV2’. Accordingly, the concentration of the positive ions in the storage channel layer 110 may decrease. In another embodiment (not illustrated), the electric field moves the oxygen ions distributed within the ion reservoir layer 130 to the storage channel layer 110. As the oxygen ions move, the concentration of the oxygen vacancies in the storage channel layer 110 may decrease.

As a result, the concentration of the positive ions or the concentration of the oxygen vacancies in the storage channel layer 110 may decrease due to the second write voltage. As the concentration of the positive ions or the concentration of the oxygen vacancies in the storage channel layer 110 decreases, the channel conductance of the storage channel layer 110 may decrease. After the channel conductance of the storage channel layer 110 is decreased, the control voltage is removed to turn off the control element CTD, and the second write voltage applied to the floating gate electrode layer 140 is removed. Even after the second write voltage is removed, the storage channel layer 110 may maintain a decreased channel conductance so that the electro-chemical memory element ECMD can store the channel conductance as signal information.

In an embodiment, the channel conductance of the storage channel layer 110 may linearly decrease in proportion to the concentration of the positive ions or the concentration of the oxygen vacancies. In an embodiment, the second write voltage may be provided in the form of a pulse voltage in substantially the same manner described above with respect to the first write voltage.

Referring to FIG. 6, as the number of pulses in the second write voltage, which are applied to the floating gate electrode layer 140, increases, the amount of the positive ions moving from the storage channel layer 110 to the ion reservoir layer 130 or the amount of the oxygen ions moving from the ion reservoir layer 130 to the storage channel layer 110 may increase. As a result, the channel conductance of the storage channel layer 110 may linearly decrease in proportion to the number of pulses of the second write voltage. Therefore, it is possible to effectively use a plurality of channel conductance values to store multi-level signal information, where the plurality of channel conductance values in the storage channel layer 110 vary according to a linear relationship.

As described above, an electro-chemical memory element according to an embodiment of the present disclosure can implement multi-level signal information that changes linearly in proportion to the applied write voltage. As will be described below, the memory cell can be applied to a computing-in-memory (CiM) device that stores the multi-level signal information as a weight and performs a MAC (Multiply-Accumulate) operation using the weight.

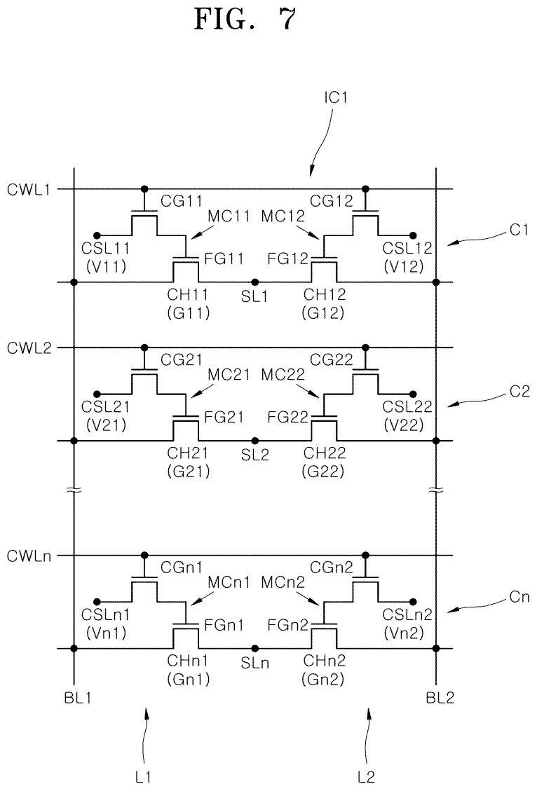

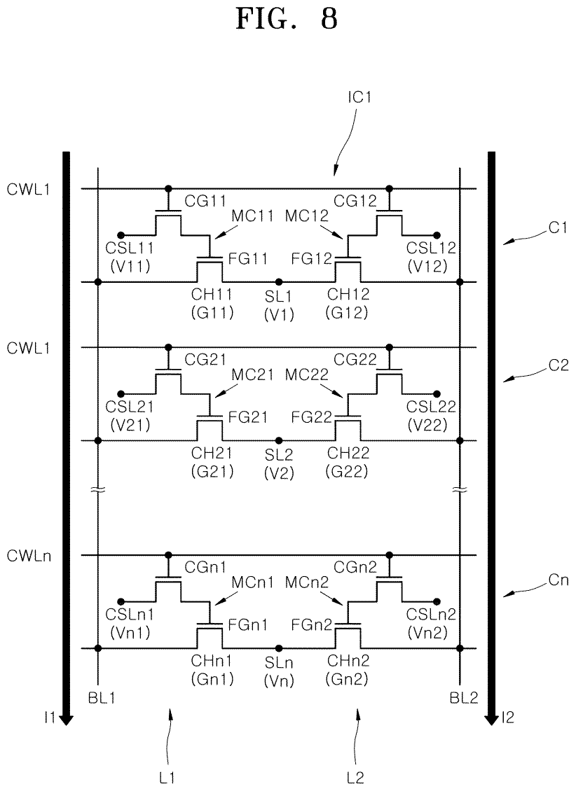

FIGS. 7 and 8 are circuit diagrams of a semiconductor device according to an embodiment of the present disclosure. Referring to FIGS. 7 and 8, a semiconductor device IC1 includes a plurality of memory cells MC11, MC21, . . . , MCn1, MC12, MC22, . . . , and MCn2. The configuration of each of the plurality of memory cells MC11, MC21, . . . , MCn1, MC12, MC22, . . . , and MCn2 may be substantially the same as the configuration of a memory cell MC1 of FIG. 1. The plurality of memory cells MC11, MC21, . . . , MCn1, MC12, MC22, . . . , and MCn2 of the semiconductor device IC1 may be applied to a CiM device that performs a MAC operation.

FIGS. 7 and 8 illustrate a semiconductor device IC1 in which n memory cells MC11, MC21, . . . , and MCn1 are disposed in a first column L1 and n memory cells MC12, MC22, . . . , and MCn2 are disposed in a second column L2. However, for convenience in explanation, some memory cells are omitted, and only the first memory cell MC11, the second memory cell MC21, and the n^{th} memory cell MCn1 are shown in the first column L1, and only the first memory cell MC12, the second memory cell MC22, and the n^{th} memory cell MCn2 are shown in the second column L2.

Referring to FIGS. 7 and 8, the first to n^{th} memory cells MC11, MC21, . . . , and MC1n of the first column L1 share a first bit line BL1. The first to n^{th} memory cells MC12, MC22, . . . , and MC2n of the second row L2 share a second bit line BL2.

A pair of first memory cells MC11 and MC12 in a first row C1 share a first control word line CWL1 and a first source line SL1. A pair of second memory cells MC21 and MC22 in a second row C2 share a second control word line CWL2 and a second source line SL2. In the manner, a pair of n^{th} memory cells MCn1 and MCn2 in the n^{th} row Cn share an n^{th} control word line CWLn and an n^{th} source line SLn.

The first to n^{th} memory cells MC11, MC21, . . . , and MCn1 of the first column L1 have corresponding control source lines CSL11, CSL21, . . . , and CSLn1, respectively. In addition, the first to n^{th} memory cells MC11, MC21, . . . , and MCn1 of the first column L1 have corresponding floating gate electrodes FG11, FG21, . . . , and FGn1, respectively, and corresponding channels CH11, CH21, . . . , and CHn1, respectively. In the same manner, the first to n^{th} memory cells MC12, MC22, . . . , and MCn2 of the second column L2 have corresponding control source lines CSL12, CSL22, . . . , and CSLn2, respectively. In addition, the first to n^{th} memory cells MC12, MC22, . . . , and MCn2 of the second column L2 have corresponding floating gate electrodes FG12, FG22, . . . , and FGn2, respectively, and corresponding channels CH12, CH22, . . . , and CHn2, respectively.

Hereinafter, with reference to FIG. 7, an operation of writing weights for performing a MAC operation in the plurality of memory cells MC11, MC21, . . . , MCn1, MC12, MC22, . . . , and MCn2 will be described. The weights are stored in the corresponding channels CH11, CH21, . . . , CHn1, CH12, CH22, . . . , and CHn2 of the plurality of memory cells MC11, MC21, . . . , MCn1, MC12, MC22, . . . , and MCn2, respectively, as channel conductances G11, G21, . . . , Gn1, G12, G22, . . . , Gn2, respectively.

First, when a gate voltage of a threshold voltage or higher is applied to the first control word line CWL1, the control gate electrodes CG11 and CG12 of the pair of first memory cells MC11 and MC12 of the first row C1 are turned on. With the control gate electrodes CG11 and CG12 turned on, when control voltages V11 and V12 are applied to the pair of control source lines CSL11 and CSL12, respectively, write voltages may be applied to a pair of floating gate electrodes FG11 and F12. Channel conductances G11 and G12 may be stored in a pair of channels CH11 and CH12, respectively, by the write voltages.

In addition, when the gate voltage of the threshold voltage or higher is applied to the second control word line CWL2 and control voltages V21 and V22 are applied to a pair of control source lines CSL21 and CSL22, channel conductances G21 and G22 may be stored in the pair of channels CH21 and CH22. In the same manner, when a gate voltage of the threshold voltage or higher is applied to the n^{th} control word line CWLn and control voltages Vn1 and Vn2 are applied to a pair of control source lines CSLn1 and CSLn2, channel conductances Gn1 and Gn2 may be stored in the pair of channels CHn1 and CHn2.

The channel conductances stored in the plurality of memory cells MC11, MC21, . . . , MCn1, MC12, MC22, . . . , and MCn2 of the semiconductor device IC1 form a matrix of two rows and n columns, as shown in Equation (1) below.

$$( \begin{matrix}G 11 & G 21 & … & … & Gn 1 \\ G 12 & G 22 & … & … & Gn 2\end{matrix} ) \qquad ( 1 )$$

Hereinafter, with reference to FIG. 8, an operation of performing a MAC operation using weights stored in the plurality of memory cells MC11, MC21, . . . , MCn1, MC12, MC22, . . . , and MCn2 will be briefly described.

In FIG. 8, channel conductances G11, G21, . . . , Gn1, G12, G22, . . . , and Gn2 are stored in the channels CH11, CH21, . . . , CHn1, CH12, CH22, . . . , and CHn2 of the plurality of memory cells MC11, MC21, . . . , MCn1, MC12, MC22, . . . , and MCn2, respectively. First to n^{th} source voltages V1, V2, . . . , and Vn are applied to the first to n^{th} source lines SL1, SL2, . . . , and SLn, respectively. Subsequently, in the first column L1, a MAC operation is performed between the first to n^{th} source voltages V1, V2, . . . , and Vn and the channel conductances G11, G21, . . . , and Gn1 of the first to n^{th} channels CH11, CH21, . . . , and CHn1 to output a first bit line current 11 through the first bit line BL1. In addition, in the second column L2, a MAC operation is performed between the first to n^{th} source voltages V1, V2, . . . , and Vn and the channel conductances G12, G22, . . . , and Gn2 of the first to n^{th} channels CH12, CH22, . . . , and CHn2 to output a second bit line current 12 through the second bit line BL2.

The MAC operation may proceed as in Equation (2) below.

$$( \begin{matrix}I 1 \\ I 2\end{matrix} ) = ( \begin{matrix}G 11 & G 21 & … & … & Gn 1 \\ G 12 & G 22 & … & … & Gn 2\end{matrix} ) ( \begin{matrix}V 1 \\ V 2 \\ ⋮ \\ V n\end{matrix} ) \qquad ( 2 )$$

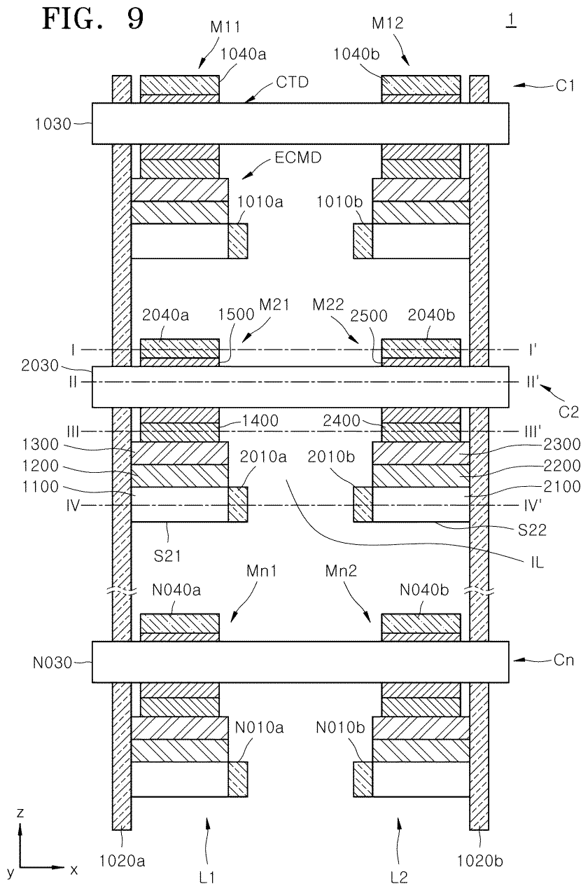

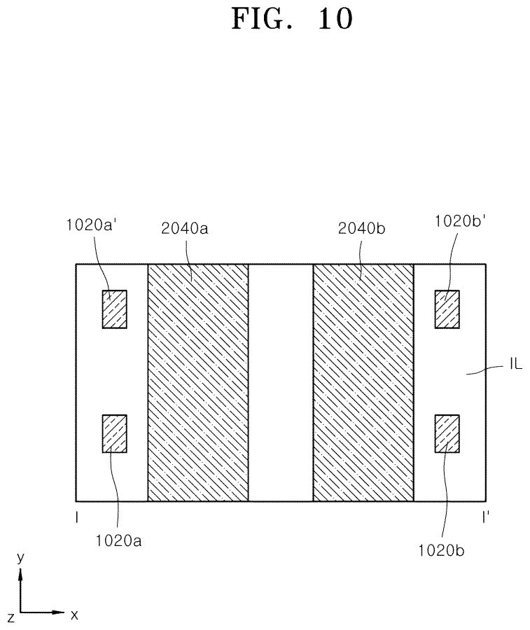

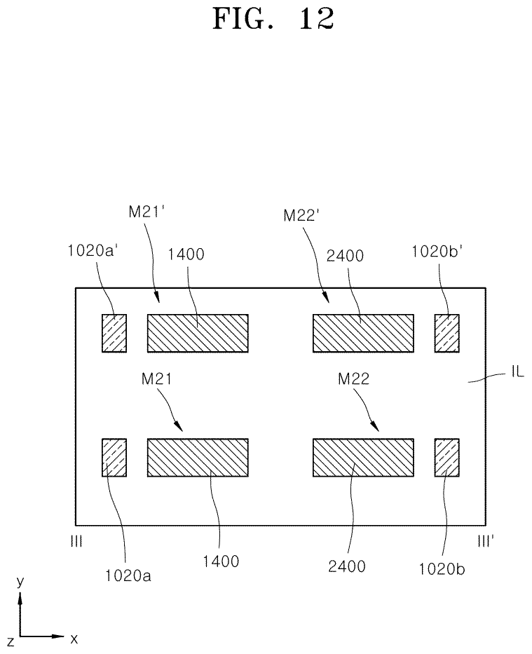

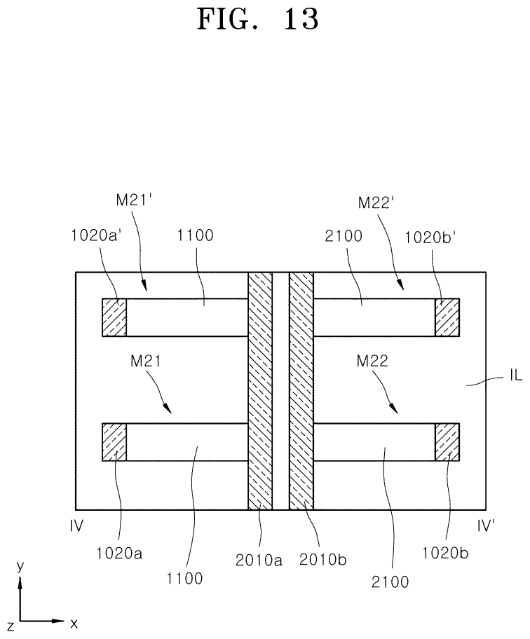

FIG. 9 is a schematic cross-sectional view illustrating a semiconductor device according to another embodiment of the present disclosure. FIG. 10 is a view illustrating a semiconductor device of FIG. 9 taken along a line I-I′ and shown on an x-y plane. FIG. 11 is a view illustrating a semiconductor device of FIG. 9 taken along a line II-II′ and shown on an x-y plane. FIG. 12 is a view illustrating a semiconductor device of FIG. 9 taken along a line III-III′ and shown on an x-y plane. FIG. 13 is a view illustrating a semiconductor device of FIG. 9 taken along a line IV-IV′ and shown on an x-y plane.

Referring to FIG. 9, a semiconductor device 1 includes a plurality of memory cells. In FIG. 9, for convenience, some memory cells are omitted, and only a first memory cell M11, a second memory cell M21, and an n^{th} memory cell Mn1 are shown in a first column L1. In addition, in a second column L2, only a first memory cell M12, a second memory cell M22, and an n^{th} memory cell Mn2 are shown.

The configuration of each of the plurality of memory cells may be substantially the same as that of a memory cell M described above with reference to FIG. 2. As an example, each of the plurality of memory cells includes a control element CTD and an electro-chemical memory element ECMD that are electrically connected to each other.

The circuit configuration of the semiconductor device 1 may follow the circuit diagram of a semiconductor device IC1 described with reference to FIGS. 7 and 8. Specifically, in the semiconductor device 1, first to n^{th} memory cells M11, M21, . . . , and Mn1 located in first column L1 share a first bit line 1020a. In addition, in the semiconductor device 1, first to n^{th} memory cells M21, M22, . . . , and Mn2 located in the second column L2 share a second bit line 1020b.

In addition, a pair of first memory cells M11 and M12 of a first row C1 share a first control word line 1030. The pair of first memory cells M11 and M12 have corresponding control source lines 1040a and 1040b and corresponding source lines 1010a and 1010b, respectively. Although not shown, the source lines 1010a and 1010b of the pair of first memory cells M11 and M12 may be electrically connected to each other. That is, the source lines 1010a and 1010b have the same electric potential during an operation of the semiconductor device 1.

A pair of second memory cells M21 and M22 of a second row C2 share a second control word line 2030. The pair of second memory cells M21 and M22 have corresponding control source lines 2040a and 2040b and corresponding source lines 2010a and 2010b, respectively. Although not shown, the source lines 2010a and 2010b of the pair of second memory cells M21 and M22 may be electrically connected to each other. Likewise, a pair of n^{th} memory cells Mn1 and Mn2 of an n^{th} row Cn share an n^{th} control word line N030. The pair of n^{th} memory cells Mn1 and Mn2 have corresponding control source lines N040a and N040b and corresponding source lines N010a and N010b, respectively. Although not shown, the source lines N010a and N010b of the pair of n^{th} memory cells Mn1 and Mn2 may be electrically connected to each other.

Although not shown in FIG. 9, the semiconductor device 1 may further include memory cells arranged in the y-direction. As an example, referring to FIGS. 11 to 13, the semiconductor device 1 may further include a pair of memory cells M21′ and M22′ disposed to be spaced apart in the y-direction from the pair of second memory cells M21 and M22 disposed at the second row C2. The memory cells M21 and M21′ disposed to be spaced apart from each other in the y-direction share the control source line 2040a and the source line 2010a. The memory cells M22 and M22′ disposed to be spaced apart from each other in the y-direction share the control source line 2040b and the source line 2010b. Likewise, the remaining memory cells of the semiconductor device 1 may further include memory cells arranged to be spaced apart from each other in the y-direction and sharing control source lines and source lines. Memory cells may be repeatedly arranged in the y-direction.

Hereinafter, with reference to FIGS. 9 to 13, the configuration of the semiconductor device 1 will be described in more detail using the plurality of second memory cells M21, M21′, M22, and M22′ arranged in the second row C2. For the convenience, the second memory cell M21 located in the first column L1 of FIG. 9 is referred to as the left memory cell M21, and the second memory cell M22 located in the second column L2 of FIG. 9 is referred to as the right memory cell M22.

Referring to FIGS. 9 to 13, the semiconductor device 1 includes a pair of first bit lines 1020a and 1020a′ and a pair of second bit lines 1020b and 1020b′ which extend in a first direction (that is, z-direction) perpendicular to a substrate. The pair of first bit lines 1020a and 1020a′ and the pair of second bit lines 1020b and 1020b′ are arranged to be spaced apart and electrically insulated from each other.

Referring to FIGS. 9 and 13, the left memory cell M21 includes a storage channel layer 1100 and a source line 2010a that are disposed on a plane S21 over the substrate. The storage channel layer 1100 has a predetermined channel length along a third direction (that is, x-direction) perpendicular to the first and second directions.

In the left memory cell M21, the source line 2010a contacts one end of the storage channel layer 1100. In addition, the source line 2010a is disposed to extend in the second direction (that is, y-direction). Accordingly, the source line 2010a contacts one end of the storage channel layer 1100 of another memory cell M21′, which is disposed to be spaced apart from the left memory cell M21 in the second direction.

Each of the pair of first bit lines 1020a and 1020a′ contacts the other end of the storage channel layer 1100. The pair of first bit lines 1020a and 1020a′ are electrically connected to the source line 2010a by the corresponding storage channel layer 1100. In another memory cell M21′ sharing a source line 2010a with the left memory cell M21, the other end of the storage channel layer 1100 is electrically connected to the other first bit line 1020a′, which is spaced apart from the first bit line 1020a in the y-direction.

In the same manner, the right memory cell M22 includes a storage channel layer 2100 and a source line 2010b that are disposed on a plane S22 over the substrate. The storage channel layer 2100 has a predetermined channel length along the third direction (that is, x-direction).

In the right memory cell M22, the source line 2010b contacts one end of the storage channel layer 2100. In addition, referring to FIG. 13, the source line 2010b is disposed to extend in the second direction (that is, y-direction). Accordingly, the source line 2010b contacts one end of the storage channel layer 2100 of another memory cell M22′, which is disposed to be spaced apart from the right memory cell M22 in the second direction.

Each of the pair of second bit lines 1020b and 1020b′ contacts the other end of the corresponding storage channel layer 2100. Each of the pair of second bit lines 1020b and 1020b′ is electrically connected to the source line 2010b by a corresponding storage channel layer 2100. Referring to FIG. 13, in the other memory cell M22′ sharing the source line 2010b with the right memory cell M22, the other end of the storage channel layer 2100 is electrically connected to the other second bit line 1020b′, which is spaced apart from the second bit line 1020b in the y-direction.

Although not shown in FIGS. 9 and 13, the source line 2010a of the left memory cell M21 and the source line 2010b of the right memory cell M22 may be electrically connected to each other. Accordingly, when the semiconductor device 1 operates, the pair of source lines 2010a and 2010b can maintain the same potential.

The configurations of the source lines 2010a and 2010b, the storage channel layers 1100 and 2100, the first bit lines 1020a and 1020a′, and the second bit lines 1020b and 1020b′ may be substantially the same as those of the source line 501, the storage channel layer 110, and the bit line 502, respectively, described above with reference to FIG. 2.

Referring to FIG. 9, in the left memory cell M21, an electrolyte layer 1200 is disposed on the storage channel layer 1100. An ion reservoir layer 1300 is disposed on the electrolyte layer 1200. The floating gate electrode layer 1400 is disposed on the ion reservoir layer 1300. As shown in FIG. 12, the floating gate electrode layer 1400 of the left memory cell M21 is disposed to be spaced apart from the first bit line 1020a. In the same manner, in the right memory cell M22, an electrolyte layer 2200 is disposed on the storage channel layer 2100. An ion reservoir layer 2300 is disposed on the electrolyte layer 2200. A floating gate electrode layer 2400 is disposed on the ion reservoir layer 2300. The floating gate electrode layer 2400 of the right memory cell M22 is disposed to be spaced apart from the second bit line 1020b.

The configurations of the electrolyte layers 1200 and 2200, the ion reservoir layers 1300 and 2300, and the floating gate electrode layers 1400 and 2400 may be substantially the same as those of the electrolyte layer 120, the ion reservoir layer 130, and the floating gate electrode layer 140 described above with reference to FIG. 2.

Referring to FIG. 9, control channel structures 1500 and 2500 are disposed on the floating gate electrode layers 1400 and 2400 of the left and right memory cells M21 and M22, respectively. The control channel structures 1500 and 2500 may be substantially the same as the control channel structure 150 described above with reference to FIG. 2. Referring to FIGS. 9 and 11 together, each of the control channel structures 1500 and 2500 is a pillar structure in the form of a square pillar, but the shape of the pillar structure is not necessarily limited thereto, and the structure may have the form of a cylinder, an elliptical pillar, or various polygonal pillars.

The control channel structures 1500 and 2500 are disposed to overlap the floating gate electrode layers 1400 and 2400, respectively, in the first direction (that is, z-direction). Referring to FIG. 11, the control channel structures 1500 and 2500 are disposed to be spaced apart from the first and second bit lines 1020a, 1020a′, 1020b, and 1020b′ in a lateral direction (for example, x-direction).

The control gate dielectric layers 1600 and 2600 are disposed on side surfaces of the control channel structures 1500 and 2500, respectively. Referring to FIG. 11, the control gate dielectric layers 1600 and 2600 are disposed on side surfaces of the control channel structures 1500 and 2500, respectively, on an x-z plane. The configurations of the control gate dielectric layers 1600 and 2600 may be substantially the same as that of the control gate dielectric layer described above with respect to FIG. 2.

Control word lines 2030 and 2030′ are disposed on control gate dielectric layers 1600 and 2600. The control word lines 2030 and 2030′ extend in the third direction (that is, x-direction) on the x-z plane. The configurations of the control word lines 2030 and 2030′ may be substantially the same as that of the control word line 504 described above with reference to FIG. 2.

Referring to FIG. 11, the control word line 2030 is disposed to be spaced apart from the bit lines 1020a and 1020b in the second direction (that is, y-direction). The memory cell M21 and the memory cell M22 share the control word line 2030, which is disposed to contact the control gate dielectric layers 1600 and 2600 of the memory cell M21 and the memory cell M22 respectively. The control word line 2030′ is disposed to be spaced apart from the bit lines 1020a′ and 1020b′ in the second direction (that is, y-direction). The memory cell M21′ and the memory cell M22′ share the control word line 2030′, which is disposed to contact the control gate dielectric layers 1600 and 2600 of the memory cell M21′ and the memory cell M22′ respectively.

Referring to FIG. 9, control source lines 2040a and 2040b may be disposed on the control channel structures 1500 and 2500, respectively. The configurations of the control source lines 2040a and 2040b may be substantially the same as the configuration of the control source line 503 described above with reference to FIG. 2.

Referring to FIG. 10, the control source lines 2040a and 2040b extend in the second direction (that is, the y-direction) on an x-y plane. The control source line 2040a is disposed to be spaced apart from the bit lines 1020a and 1020a′ in the third direction (that is, x-direction). The memory cell M21 and the memory cell M21′ share the control source line 2040a. Additionally, the control source line 2040b is disposed to be spaced apart from the bit lines 1020b and 1020b′ in the third direction (that is, the x-direction). The memory cell M22 and the memory cell M22′ share the control source line 2040b.

An interlayer insulation layer IL is disposed in the space between the numbered components in FIGS. 9 to 13. The interlayer insulation layer IL serves to electrically insulate numbered components from each other.

As described above, according to an embodiment of the present disclosure, a semiconductor device with a three-dimensional structure can be effectively implemented with pairs of memory cells spaced apart in a third direction (that is, x-direction) that share a control word line that also extends in the third direction (that is, x-direction), pairs of memory cells may be stacked in the first direction (that is, z-direction). As described above, according to an embodiment of the present disclosure, a semiconductor device with a three-dimensional structure can be effectively implemented with pairs of memory cells spaced apart in a second direction (that is, y-direction) that also share a source line and a control source line, both of which extend in the second direction. The pairs of memory cells may be stacked in the first direction (that is, z-direction).

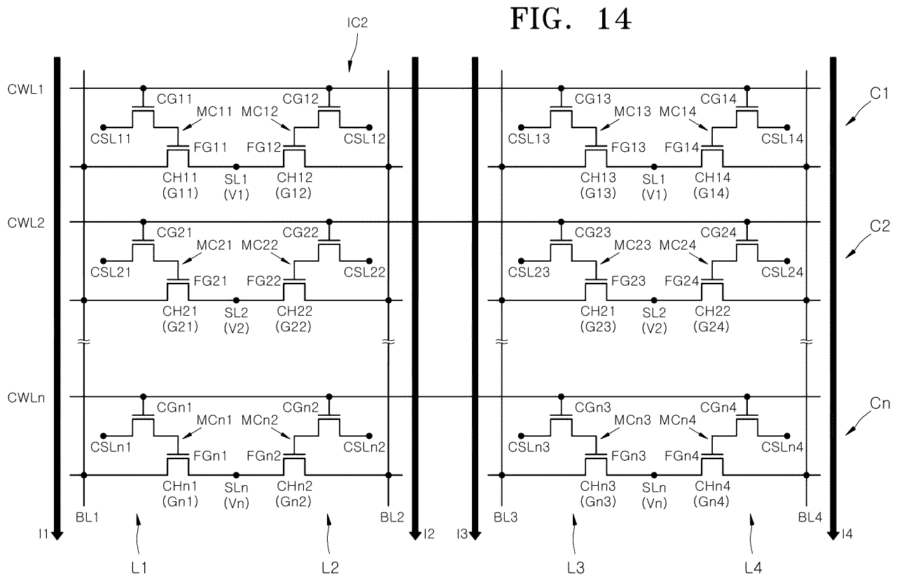

FIG. 14 is a circuit diagram of a semiconductor device according to another embodiment of the present disclosure. Referring to FIG. 14, compared to a semiconductor device IC1 described above with reference to FIG. 7, a semiconductor device IC2 further includes a plurality of memory cells MC13, MC23, . . . . MCn3, MC14, MC24, . . . , and MCn4 in third and fourth columns L3 and L4 arranged along the x-direction.

The configurations of the plurality of memory cells MC13, MC23, . . . . MCn3, MC14, MC24, . . . , and MCn4 in the third and fourth columns L3 and L4 may be substantially the same as those of the plurality of memory cells MC11, MC21, . . . . MCn1, MC12, MC22, . . . , and MCn2 in the first and second columns L1 and L2.

The plurality of memory cells MC13, MC23, . . . , and MCn3 of the third column L3 store a plurality of channel conductances G13, G23, . . . , and Gn3 in a plurality of channels CH13, CH23, . . . , and CHn3, respectively, by a gate voltage applied from a plurality of control word lines CWL1, CWL2, . . . , and CWLn and a write voltage applied to the plurality of floating gate electrodes FG13, FG23, . . . , and FGn3 through a plurality of control source lines CSL13, CSL23, . . . , and CSLn3. In the same manner, the plurality of memory cells MC14, MC24, . . . , and MCn4 of the fourth column L4 store a plurality of channel conductances G14, G24, . . . , and Gn4 in a plurality of channels CH14, CH24, . . . , and CHn4, respectively, by the gate voltage applied from the plurality of control word lines CWL1, CWL2, . . . , and CWLn and a write voltage applied to the plurality of floating gate electrodes FG14, FG24, . . . , and FGn4 through a plurality of control source lines CSL14, CSL24, . . . , and CSLn4, respectively. As a result, the plurality of channel conductances stored in the memory cells of four columns and three rows of the semiconductor device IC2 can be used as weights for a MAC operation.

Subsequently, first to n^{th} source voltages V1, V2, . . . , and Vn are input to first to n^{th} source lines SL1, SL2, . . . , and SLn of the semiconductor device IC2 of FIG. 14, respectively, and accordingly, a MAC operation is performed on the plurality of memory cells MC11, MC21, . . . . MCn1, MC12, M22, . . . , MCn2, MC13, MC23, . . . . MCn3, MC14, MC24, . . . , and MCn4.

The MAC operation may proceed as a process of obtaining first to fourth bit line currents 11, 12, 13, and 14 output through the first to fourth bit lines BL1, BL2, BL3, and BL4, respectively. Equation (3) below illustrates a determinant of the MAC operation.

$$( \begin{matrix}I 1 \\ I 2 \\ I 3 \\ I 4\end{matrix} ) = ( \begin{matrix}G 11 & G 21 & … & … & Gn 1 \\ G 12 & G 22 & … & … & Gn 2 \\ G 13 & G 23 & … & … & Gn 3 \\ G 14 & G 24 & … & … & Gn 4\end{matrix} ) ( \begin{matrix}V 1 \\ V 2 \\ V 3 \\ V 4\end{matrix} ) \qquad ( 3 )$$

As described above, the circuit diagram of FIG. 14 illustrates a plurality of memory cells arranged in four columns and three rows, but the presently disclosed concept is not necessarily limited thereto. As long as the conditions for performing the MAC operation are met, different numbers of memory cells arranged in various numbers of columns and rows can also be applied, and the columns and rows illustrated in FIG. 14 may be arranged in a three-dimensional structure by repeated arrangement in a lateral direction.

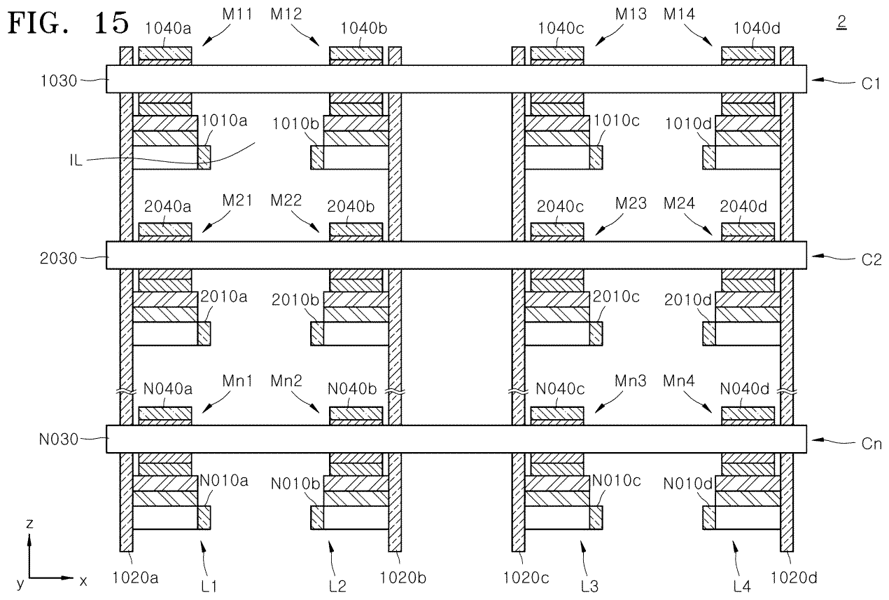

FIG. 15 is a schematic cross-sectional view illustrating a semiconductor device according to another embodiment of the present disclosure. A semiconductor device 2 of FIG. 15 may follow the circuit diagram of a semiconductor device IC2 in FIG. 14.

When compared to a semiconductor device 1 of FIGS. 9 to 13, the semiconductor device 2 of FIG. 15 further includes a plurality of memory cells M13, M23, . . . . Mn3, M14, M24, . . . , and Mn4 in third and fourth columns L3 and L4 that are disposed along the x-direction. The configurations of the plurality of memory cells M13, M23, . . . . Mn3, M14, M24, . . . , and Mn4 in the third and fourth columns L3 and L4 may be substantially the same as those of the plurality of memory cells M11, M21, . . . . Mn1, M12, M22, . . . , and Mn2 of the first and second columns L1 and L2.

As shown in FIG. 15, the plurality of memory cells M13, M23, . . . and Mn3 in the third column L3 share a third bit line 1020c. The plurality of memory cells M13, M23, . . . , and Mn3 of the third column L3 have corresponding source lines 1010c, 2010c, . . . , and N010c and corresponding control source lines 1040c, 2040c, . . . , and N040c, respectively. The plurality of memory cells M14, M24, . . . , and Mn4 in the fourth column L4 share the third bit line 1020d. The plurality of memory cells M14, M24, . . . , and Mn4 in the fourth column L4 have corresponding source lines 1010d, 2010d, . . . , and N010d, respectively, and corresponding control source lines 1040d, 2040d, . . . , and N040d, respectively.

FIG. 15 shows the plurality of memory cells arranged in four columns and n rows in x-z plane, but the presently disclosed concept is not necessarily limited thereto. As long as the conditions for performing a MAC operation are satisfied, other numbers of memory cells consisting of various numbers of columns and rows extending in at least one of the x-direction, y-direction, and z-direction can also be applied.

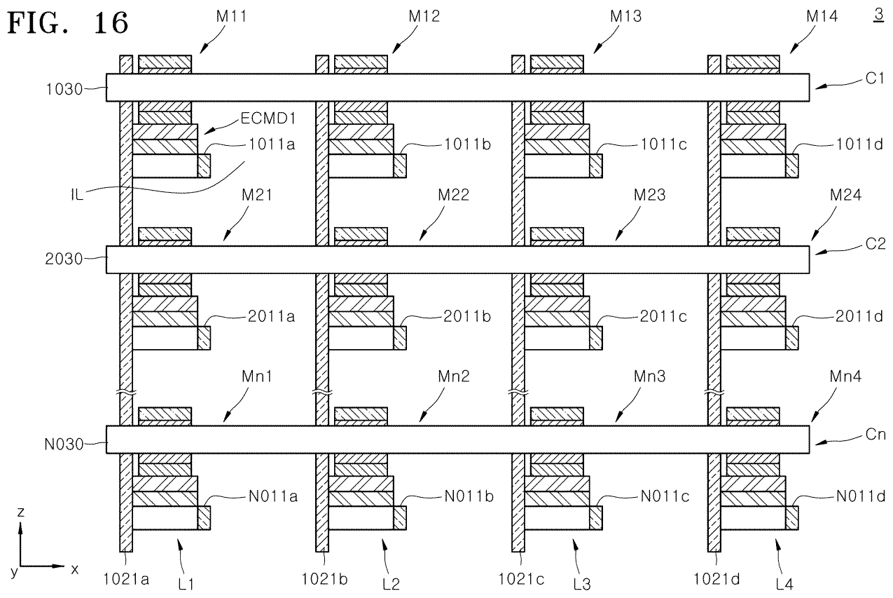

FIG. 16 is a schematic cross-sectional view illustrating a semiconductor device according to another embodiment of the present disclosure. A semiconductor device 3 of FIG. 16 has a different arrangement of bit lines 1021a, 1021b, 1021c, and 1021d and source lines 1011a, 1011b, 1011c, 1011d, 2011a, 2011b, 2011c, 2011d, N011a, N011b, N011c, and N011d, compared to those of a semiconductor device 2 of FIG. 15. The semiconductor device 3 in FIG. 16 may follow the circuit diagram of a semiconductor device IC2 of FIG. 14.

Referring to FIG. 16, in the first column L1, the first bit line 1021a is disposed on the left side of the first to n^{th} memory cells M11, M21, . . . , and Mn1, and the source lines 1011a, 2011a, . . . , and N011a are disposed on the right side of the corresponding memory cells M11, M21, . . . , and Mn1, respectively. In the second column L2, the second bit line 1021b is disposed on the left side of the first to n^{th} memory cells M12, M22, . . . , and Mn2, and the source lines 1011b, 2011b, . . . and N011b are disposed on the right side of the corresponding memory cells M12, M22, . . . , and Mn2, respectively. Similarly, in the third column L3, the third bit line 1021c is disposed on the left side of the first to n^{th} memory cells M13, M23, . . . , and Mn3, and the source lines 1011c, 2011c, . . . , and N011c are disposed on the right side of the corresponding first to n^{th} memory cells M13, M23, . . . , and Mn3, respectively. In the fourth column L4, the fourth bit line 1021d is disposed on the left side of the first to n^{th} memory cells M14, M24, . . . , and Mn4, and the source lines 1011d, 2011d, . . . , and N011d are disposed on the right side of the corresponding first to n^{th} memory cells M14, M24, . . . , and Mn4, respectively.

As described above, in semiconductor devices according to disclosed embodiments, the bit lines and the source lines may be arranged in the same manner, such as on opposite sides, in all memory cells.

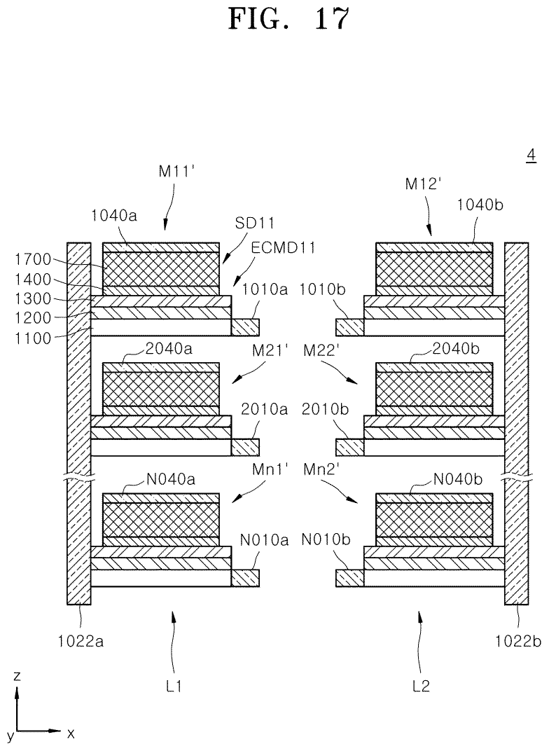

FIG. 17 is a schematic cross-sectional view illustrating a semiconductor device according to another embodiment of the present disclosure. Referring to FIG. 17, a semiconductor device 4 includes first to n^{th} memory cells M11′, M21′, . . . , and Mn1′ of a first column L1, which share a first bit line 1022a, and first to n^{th} memory cells M12′, M22′, . . . , and Mn2′ of a second column L2, which share a second bit line 1022b.

Each of the first to n^{th} memory cells M11′, M21′, . . . , Mn1′, M12′, M22′, . . . , Mn2′ of the first and second columns L1 and L2 has a control element SD and an electro-chemical memory element ECMD. In an embodiment, the control element SD may be a selection device. Each control element SD includes a threshold switching layer 1700 disposed on a floating gate electrode layer 1400. Each control element SD is connected to a corresponding control source line among control source lines 1040a, 2040a, . . . , N040a, 1040b, 2040b, . . . , and N040b disposed respectively on the threshold switching layer 1700 and extending in the second direction (that is, y-direction). The threshold switching layers 1700 are disposed to contact the control source lines 1040a, 2040a, . . . , N040a, 1040b, 2040b, . . . , and N040b and the floating gate electrode layers 1400, respectively.

When a control voltage of a threshold voltage or higher is applied to the threshold switching layer 1700 from the control source lines 1040a, 2040a, . . . , N040a, 1040b, 2040b, . . . , and N040b, a current equal to or greater than a predetermined reference current flows through the threshold switching layer 1700, and accordingly, the threshold switching layer 1700 is electrically turned on. Conversely, when a control voltage less than the threshold voltage is applied to the threshold switching layer 1700 from the control source lines 1040a, 2040a, . . . , N040a, 1040b, 2040b, . . . , N040b, a current less than the reference current flows through the threshold switching layer 1700, and accordingly, the threshold switching layer 1700 is electrically turned off. Accordingly, the threshold switching layer 1700 can more precisely control the application of write voltage to the floating gate electrode layer 1400 of the electro-chemical memory element ECMD.

In an embodiment, the threshold switching layer 1700 includes a resistance change material. As an example, the threshold switching layer 1700 includes a metal oxide containing oxygen vacancies. The metal oxide may include, for example, tantalum oxide, hafnium oxide, zirconium oxide, and hafnium zirconium oxide.

The configuration of the electro-chemical memory element ECMD is substantially the same as that of the electro-chemical memory element ECMD of a semiconductor device 1 described above in connection with FIG. 9. In an embodiment, in the plurality of memory cells of the semiconductor device 4, when the threshold switching layer 1700 is turned on, a write operation is performed by applying a write voltage from the control source line to the floating gate electrode layer in a memory cell in which the channel conductance is stored in the channel layer. In the semiconductor device 4, the process of performing a MAC operation based on a source voltage input to a plurality of source lines and the channel conductance of the plurality of memory cells may be substantially the same as that described above for a semiconductor device 1 of FIG. 9.

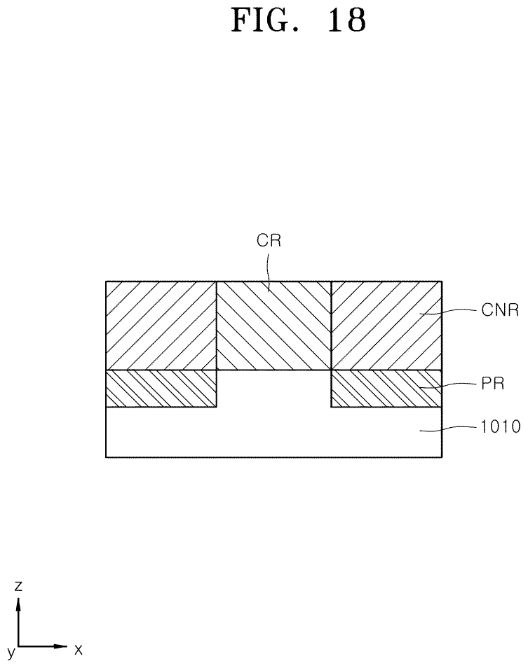

FIGS. 18 to 20 are schematic cross-sectional views illustrating arrangements of memory cells of a semiconductor device according to various embodiments of the present disclosure. The arrangement of the memory cells in FIGS. 18 to 20 may be used in the arrangement of the plurality of memory cells of a semiconductor device 1 of FIGS. 9 to 13, the plurality of memory cells of a semiconductor device 2 of FIG. 15, the plurality of memory cells of a semiconductor device 3 of FIG. 16, and the plurality of memory cells of a semiconductor device 4 of FIG. 17.

Referring to FIG. 18, in an embodiment, the plurality of memory cells of one of the semiconductor devices 1, 2, 3, and 4 are disposed in a cell region CR of a substrate 1010. A plurality of control circuits that control and drive the plurality of memory cells are disposed in a peripheral circuit region PR within the substrate 1010. The peripheral circuit region PR does not overlap the cell region CR in a vertical direction (that is, z-direction). That is, the peripheral circuit region PR may be disposed to be spaced apart from the cell region CR in the lateral direction (for example, x-direction or y-direction).

A connection region CNR is disposed directly over the peripheral circuit region PR. The connection region CNR may be disposed to be spaced apart from the cell region CR in the lateral direction (for example, x-direction or y-direction). The plurality of memory cells in the cell region CR and the plurality of control circuits in the peripheral circuit region PR are electrically connected to each other through three-dimensional interconnections disposed in the connection region CNR.

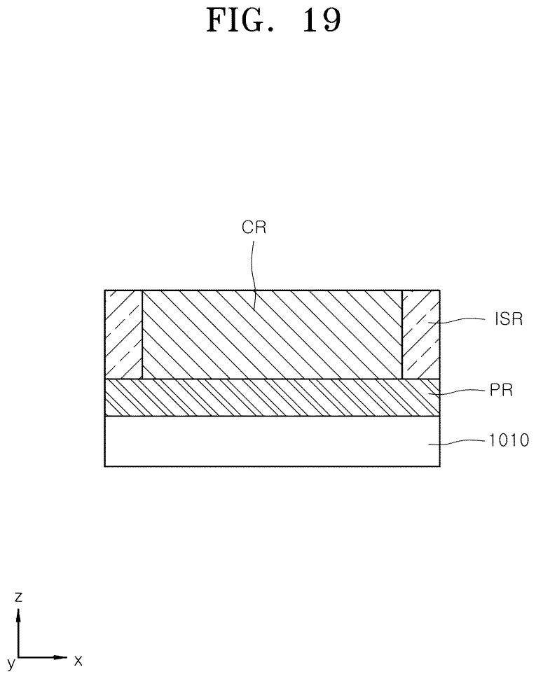

Referring to FIG. 19, in another embodiment, a peripheral circuit region PR is disposed on a substrate 1010, and a cell region CR is disposed on the peripheral circuit region PR. The cell region CR and the peripheral circuit region PR are disposed to overlap each other in a direction perpendicular to the substrate 1010 (that is, z-direction). Although not shown, the interconnections between the peripheral circuit region PR and the cell region CR may be disposed in the vertical direction (that is, z-direction) in the overlapping region of the peripheral circuit region PR and the cell region CR. An interlayer insulation layer ISR is disposed in the lateral direction (for example, x-direction or y-direction) of the cell region CR instead of the connection region (CNR in FIG. 18).

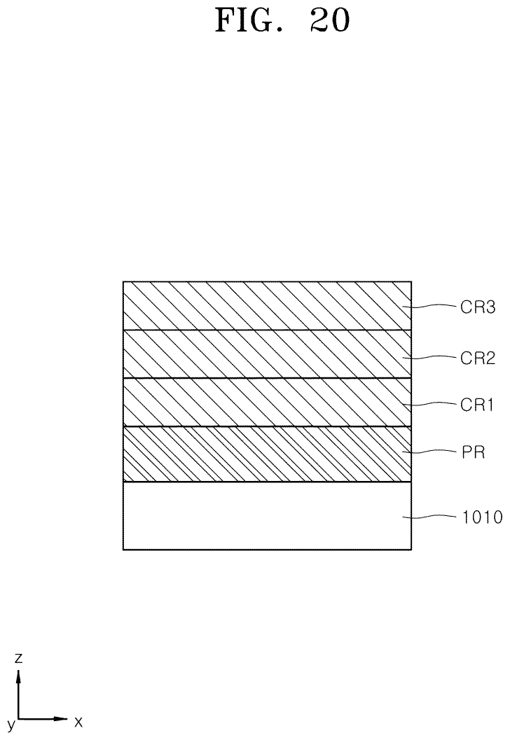

Referring to FIG. 20, in a further embodiment, a peripheral circuit region PR is disposed on a substrate 1010, and first to third cell regions CR1, CR2, and CR3 are sequentially disposed on the peripheral circuit region PR. The plurality of control circuits in the peripheral circuit region PR control the plurality of memory cells in the first to third cell regions CR1, CR2, and CR3. Accordingly, the plurality of memory cells can be effectively stacked on a cell region basis, in the direction perpendicular to the substrate 1010 (that is, z-direction). That is, a plurality of memory cells are disposed in the first cell region CR1, a plurality of other memory cells are disposed in the second cell region CR2, and a plurality of other memory cells are disposed in the third cell region CR3. As a result, by sequentially stacking the plurality of cell regions on the peripheral circuit region PR, process complexity can be reduced from stacking multiple memory cells in three dimensions, thereby reducing the process cost.

Concepts have been disclosed in conjunction with some embodiments as described above. Those skilled in the art will appreciate that various modifications, additions, and substitutions are possible, without departing from the scope and spirit of the present disclosure. Accordingly, the embodiments disclosed in the present specification should be considered from not a restrictive standpoint but rather from an illustrative standpoint. The scope of the concepts is not limited to the above descriptions but defined by the accompanying claims, and all of distinctive features in the equivalent scope should be construed as being included in the concepts.

What is claimed is:

1. A memory cell comprising an electro-chemical memory element and a control element that are electrically connected to each other,
wherein the electro-chemical memory element comprises:
a source line disposed on a plane;
a bit line disposed to be spaced apart from the source line and extending in a first direction;
a storage channel layer disposed on the plane to be connected to the source line and the bit line;
an electrolyte layer disposed on the storage channel layer;
an ion reservoir layer disposed on the electrolyte layer; and
a floating gate electrode layer disposed on the ion reservoir layer, and
wherein the control element comprises:
a control channel structure disposed on the floating gate electrode layer;
a control source line disposed on the control channel structure;
a control gate dielectric layer disposed on a side surface of the control channel structure; and
a control word line disposed on the control gate dielectric layer.

2. The memory cell of claim 1,
wherein each of the source line and the control source line extends in a second direction on a plane that is perpendicular to the first direction, and
wherein the control word line extends in a third direction that is not parallel to the first direction and on a plane parallel to the first direction.

3. The memory cell of claim 1, wherein the ion reservoir layer comprises ions that are exchangeable with the storage channel layer.

4. The memory cell of claim 3, wherein a concentration of the ions exchanged between the ion reservoir layer and the storage channel layer is controlled by a voltage applied to the floating gate electrode layer.

5. The memory cell of claim 3, wherein the ions comprise at least one of hydrogen (H) ions, lithium (Li) ions, sodium (Na) ions, potassium (K) ions, and oxygen (O) ions.

6. The memory cell of claim 3, wherein a channel conductance of the storage channel layer changes linearly depending on a concentration of the ions in the storage channel layer.

7. The memory cell of claim 1, wherein the storage channel layer receives ions provided by the ion reservoir layer.

8. The memory cell of claim 1, wherein the storage channel layer comprises at least one of metal, metal oxide, metal chalcogenide, and polycrystalline silicon.

9. The memory cell of claim 1,
wherein the ion reservoir layer comprises at least one of palladium hydride, magnesium hydride, yttrium hydride, silicon containing hydrogen, and gallium arsenide containing hydrogen,
wherein the electrolyte layer comprises at least one of proton exchange polymer, metal-organic framework, sulfonate graphene, and polymer-graphene composites, and
wherein the storage channel layer comprises at least one of palladium (Pd), magnesium (Mg), and yttrium (Y).

10. The memory cell of claim 1,
wherein the ion reservoir layer comprises LiₓMO₂ (0<x≤1), where M comprises at least one of titanium (Ti), vanadium (V), chromium (Cr), manganese (Mn), iron (Fe), cobalt (Co), and nickel (Ni)), NaₓMO₂ (0<x≤1, M comprises at least one of iron (Fe), cobalt (Co), manganese (Mn), nickel (Ni), and copper (Cu)), KₓMnO₂ (0<x≤1), and KₓCoO₂ (0<x≤1),
wherein the electrolyte layer comprises at least one of lithium phosphorus oxynitride (LiPON), a sulfonated tetrafluoroethylene based fluoropolymer-copolymer, a polystyrene-based membrane, a sulfonated polyimide (SPI)-based membrane, a polyphosphazene-based membrane, and a polybenzimidazole (PBI)-based membrane, and
wherein the storage channel layer comprises at least one of tungsten oxide (WO₃), molybdenum sulfide (MoS₂), tungsten sulfide (WS₂), and tin sulfide (SnS₂).

11. The memory cell of claim 1,
wherein the ion reservoir layer comprises at least one of gadolinium oxide (GdOₓ (0<x≤1)), molybdenum oxide (MoOₓ (0<x≤1)), tungsten oxide (WO₃₋ₓ (0<x≤1)), copper oxide (CuO), and titanium oxide (TiO₂),
wherein the electrolyte layer comprises at least one of hafnium oxide (HfO₂), zirconium oxide (ZrO₂), yttria-stabilized zirconia (YSZ), barium-selenium-yttrium oxide (Ba—Ce—Y—O), and zirconium-scandium oxide (Zr—Sc−O), and
wherein the storage channel layer comprises at least one of tungsten oxide (WO₃), molybdenum oxide (MoO₃), selenium oxide (CeO₃), iron oxide (Fe₃O₄), zirconium oxide (ZrO₂), cobalt oxide (CoO), vanadium oxide (V₂O₅), titanium oxide (TiO₂), strontium titanium oxide (SrTiO₃), and yttrium oxide (Y₂O₃).

12. The memory cell of claim 1, wherein the control channel structure comprises a pillar structure that connects the floating gate electrode layer to the control source line.

13. A semiconductor device comprising:
a substrate;
a bit line extending in a first direction perpendicular to a surface of the substrate; and
a plurality of memory cells sharing the bit line, and disposed to be spaced apart from each other in the first direction and over the substrate,
each of the plurality of memory cells comprising an electro-chemical memory element,
wherein the electro-chemical memory element comprises:
a source line disposed to extend in a second direction on a plane perpendicular to the first direction over the substrate;
a storage channel layer disposed to electrically connect the source line to the bit line on the plane;
an electrolyte layer disposed on the storage channel layer;
an ion reservoir layer disposed on the electrolyte layer; and
a floating gate electrode layer disposed on the ion reservoir layer.

14. The semiconductor device of claim 13, wherein each of the plurality of memory cells further comprises a control element electrically connected to the floating gate electrode layer.

15. The semiconductor device of claim 14, wherein the control element comprises:
a control channel structure disposed on the floating gate electrode layer;
a control source line disposed on the control channel structure and extending in the second direction;
a control gate dielectric layer disposed on a side surface of the control channel structure; and
a control word line contacting the control gate dielectric layer and extending in a third direction perpendicular to the first and second directions.

16. The semiconductor device of claim 14, wherein the control element comprises:
a threshold switching layer disposed on the floating gate electrode layer; and
a control source line disposed on the threshold switching layer and extending in the second direction.

17. The semiconductor device of claim 13, wherein each of the plurality of memory cells stores signal information corresponding to a conductance value of the storage channel layer.

18. The semiconductor device of claim 13, wherein the ion reservoir layer comprises ions that are exchangeable with the storage channel layer.

19. The semiconductor device of claim 18, wherein a concentration of the ions exchanged between the ion reservoir layer and the storage channel layer is controlled by a voltage applied to the floating gate electrode layer.

20. The semiconductor device of claim 18, wherein a channel conductance of the storage channel layer changes linearly depending on a concentration of the ions in the storage channel layer.

21. The semiconductor device of claim 13, further comprising a plurality of control circuits configured to control the plurality of memory cells.

22. The semiconductor device of claim 21,
wherein the plurality of control circuits are disposed in a peripheral circuit region located on the substrate, and
wherein the plurality of memory cells are disposed in a cell region located on the peripheral circuit region.

23. A semiconductor device comprising:
a substrate;
first and second bit lines extending in a first direction perpendicular to a surface of the substrate; and
a pair of memory cells electrically connected to corresponding bit lines of the first and second bit lines and disposed to be spaced apart from each other,
each of the pair of memory cells comprising an electro-chemical memory element,
wherein the electro-chemical memory element comprises:
a source line disposed to extend in a second direction on a plane that is perpendicular to the first direction over the substrate;
a storage channel layer disposed to electrically connect the source line to a bit line on the plane;
an electrolyte layer disposed on the storage channel layer;
an ion reservoir layer disposed on the electrolyte layer; and
a floating gate electrode layer disposed on the ion reservoir layer, and
wherein the source lines of the pair of memory cells are electrically connected to each other.

24. The semiconductor device of claim 23, wherein each of the pair of memory cells further comprises a control element electrically connected to the floating gate electrode layer.

25. The semiconductor device of claim 24, wherein the control element comprises:
a control channel structure disposed on the floating gate electrode layer;
a control source line disposed on the control channel structure and extending in the second direction;
a control gate dielectric layer disposed on a side surface of the control channel structure; and
a control word line contacting the control gate dielectric layer and extending in a third direction perpendicular to the first and second directions.

26. The semiconductor device of claim 25, wherein the pair of memory cells share the control word line.

27. The semiconductor device of claim 24, wherein the control element comprises:
a threshold switching layer disposed on the floating gate electrode layer; and
a control source line disposed on the threshold switching layer and extending in the second direction.
